(19) United States
(12) Patent Application Publication
(10) Pub. No.: US 2009/0114950 A1
(43) Pub. Date: May 7, 2009

(54) Semiconductor Device and Method of Manufacturing such a Device

(75) Inventors: Prabhat Agarwal, Leuven (BE); Jan Willem Slotboom, Eersel (NL); Gerben Doornbos, Leuven (BE)

Correspondence Address: NXP, B.V.;NXP INTELLECTUAL PROPERTY DEPARTMENT, M/S41-SJ, 1109 MCKAY DRIVE, SAN JOSE, CA, 95131, US

(73) Assignee: Koninklijke Philips Electronics N.V., BA Eindhoven (NL)

(21) Appl. No.: 11/597,533

(22) PCT Filed: May 19, 2005
(86) PCT No.: PCT/IB05/51636

§ 371 Date: Nov. 22, 2006

(30) Foreign Application Priority Data
May 25, 2004 (EP) 04102284.9

(51) Int. Cl. H01L 21/336; H01L 21/8249; H01L 21/8232; H01L 29/78; H01L 29/80; H01L 21/8234; H01L 21/8248

(52) U.S. Cl. 257/192; 438/234; 438/289; 257/E29.263; 257/E29.31; 257/E21.625; 257/E21.695

(57) ABSTRACT

The invention relates to a semiconductor device (10) comprising a substrate (11) and a semiconductor body (1) of silicon having a semiconductor layer structure comprising, in succession, a first and a second semiconductor layer (2, 3), and having a surface region of a first conductivity type which is provided with a field effect transistor (M) with a channel of a second conductivity type, opposite to the first conductivity type, wherein the surface region is provided with source and drain regions (4A, 4B) of the second conductivity type for the field effect transistor (M) and with—interposed between said source and drain regions—a channel region (3A) with a lower doping concentration which forms part of the second semiconductor layer (3) and with a buried first-conductivity-type semiconductor region (2A), buried below the channel region (3A), with a doping concentration that is much higher than that of the channel region (3A) and which forms part of the first semiconductor layer (2). According to the invention, the semiconductor body (1) is provided not only with the field effect transistor (M) but also with a bipolar transistor (B) with emitter, base and collector regions (5A, 5B, 5C) of respectively the second, the first and the second conductivity type, and the emitter region (5A) is formed in the second semiconductor layer (3) and the base region (5B) is formed in the first semiconductor layer (2). In this way a Bi(C)MOS IC (10) is obtained which is very suitable for high-frequency applications and which is easy to manufacture using a method according to the invention. Preferably the first semiconductor layer (2) comprises Si—Ge and is delta-doped, whereas the second semiconductor layer (3) comprises strained Si.

The invention relates to a semiconductor device comprising a substrate and a semiconductor body of silicon having a semiconductor layer structure including, in succession, at least a first and a second semiconductor layer, and having a surface region of a first conductivity type which is provided with a field effect transistor with a channel of a second conductivity type, opposite to the first conductivity type, wherein the surface region is provided with source and drain regions of the second conductivity type for the field effect transistor and with—interposed between said source and drain regions—a channel region with a low doping concentration which forms part of the second semiconductor layer and with a buried semiconductor region of the first conductivity type which is situated under the channel region and which has a doping concentration that is much higher than that of the channel region and which forms part of the first semiconductor layer. The invention also relates to a method of manufacturing such a device. It is to be noted that the term “channel” is to be taken to mean the thin conductive region between source and drain, which is formed during operation of the transistor. The term “surface region” is to be taken to mean a part of the semiconductor body situated at the surface thereof, which comprises, inter alia, the channel region and the channel to be formed therein.

Such a device and method are known from United States patent specification U.S. Pat. No. 6,271,551, published on 7 Aug. 2001. In said document a description is given of a MOS (=Metal Oxide Semiconductor) transistor comprising a lightly doped channel zone and, below said channel zone, a highly doped buried zone, for example p-type in a NMOS transistor, which serves as the ground area. By virtue thereof, this transistor exhibits, on the one hand, a high mobility in the channel region, while, on the other hand, so-termed short-channel effects are suppressed, as a result of which variations in the threshold voltage and the occurrence of so-termed punch-through effects are precluded. In the known transistor, a semiconductor region containing SiGe is present between the channel zone and the buried-notably p-type-zone, as a result of which undesirable diffusion from the buried zone to the channel zone is suppressed. Both the channel zone and the buried zone form part of a semiconductor layer structure. The buried zone is formed so as to be an implanted semiconductor layer, the channel zone is formed by a layer-shaped part of the semiconductor body adjoining the surface of said semiconductor body. The known device is very suitable for the manufacture of ICs (=Integrated Circuits) comprising a CMOS (=Complementary MOS) circuit for high-frequency signal processing and/or digital logic applications.

A drawback of the known device resides in that it is inadequate for many applications in the high-frequency range, such as mobile telephony or optical networks.

Therefore it is an object of the present invention to provide a device which is suitable for said applications and which is very easy to manufacture.

To achieve this, a device of the type mentioned in the opening paragraph is characterized in accordance with the invention in that the semiconductor body is provided not only with said field effect transistor but also with a bipolar transistor having an emitter region, a base region and a collector region of, respectively, the second, the first and the second conductivity type, and the emitter region is formed in the second semiconductor layer and the base region is formed in the first semiconductor layer. The invention is based first of all on the recognition that said applications frequently require, in addition to signal processing means, a transmission and/or receiving circuit.

Bipolar transistors are suitable for this purpose, and the present invention is further based on the recognition that integration of such bipolar transistors in the device comprising (a large number of) MOS transistors is conducive, on the one hand, to bipolar transistors having high-frequency properties and, on the other hand, that such an integration can be achieved in a very simple manner. This can be attributed to the fact that a highly doped, preferably delta-doped, base region improves the high-frequency properties of a bipolar transistor and to the fact that the base region of the bipolar transistor can be formed simultaneously with the highly doped buried zone of the MOS transistor, as a result of which the manufacturing process remains simple. The invention is further based on the recognition that the emitter region may also be readily formed in the second semiconductor layer. To allow the MOS transistor to operate as a channel region, this layer should be lightly doped; and a highly doped emitter region of the opposite conductivity type can be readily locally formed in said layer by locally introducing the desired impurities in a high concentration into said layer.

The invention is finally based on the recognition that a mixed crystal of Si and Ge in or near the first semiconductor layer is advantageous not only for the MOS transistor but also for use in the bipolar transistor formed.

In a preferred embodiment of a semiconductor device in accordance with the invention, both the first and the second semiconductor layer are formed by means of epitaxy. Although the semiconductor layers may alternatively both be formed by means of, for example, ion implantation, the use of epitaxy offers various important advantages. The latter technique in particular enables providing the first semiconductor layer with a very high doping and providing the doping profile with a delta shape, also referred to as spike shape. In addition, both the MOS transistor and the bipolar transistor can be readily formed by means of a predominantly epitaxial process, in which the desired isolation regions can also be readily formed. In this case, both parts of the device are of the so-termed differential type, which means that part of the MOS transistor and of the bipolar transistor is situated above the isolation regions, which parts contain non-monocrystalline material.

Preferably, the first semiconductor layer comprises a mixed crystal of silicon and germanium, and the second semiconductor layer contains silicon. Said layer may be used in the MOS transistor to fulfill the well-known function of diffusion barrier, while the SiGe leads to a further improvement of the high-frequency properties of the bipolar transistor by virtue of its smaller bandgap in said transistor. The thickness of the first semiconductor layer or of a SiGe-containing further semiconductor layer bordering said first semiconductor layer preferably on the lower side thereof, is advantageously chosen to be such that the silicon-containing second semiconductor layer, which has a smaller lattice constant than a SiGe-containing layer, is mechanically stressed. Such stress increases the mobility of the charge carriers in the channel region, causing the high-frequency properties of the MOS transistor to be improved, while it does not have any adverse effects at the location of the bipolar transistor.

In a favorable modification thereof, below the first semiconductor layer or below the further semiconductor layer adjoining said first semiconductor layer, another semiconductor layer is situated containing a mixed crystal of silicon and germanium, the germanium content gradually increasing, in the direction of the first semiconductor layer, from zero to the germanium content of the first semiconductor layer. Such a buffer layer precludes the development of crystal damage in the semiconductor body or precludes at least that the defects accompanying such crystal damage can reach the active region of the MOS transistor and the bipolar transistor, and adversely affect the properties thereof.

As mentioned hereinabove, the first semiconductor layer is preferably provided with a concentration profile of doping elements for the first conductivity type, which is delta or spike-shaped in the thickness direction. Part of a SiGe-containing first semiconductor layer is consequently situated between the buried zone and the channel region of the MOS transistor and hence can serve as a diffusion barrier between the two.

The emitter region of the bipolar transistor is preferably formed by locally introducing suitable impurities into the second semiconductor layer, preferably by means of outdiffusion from a superjacent polycrystalline silicon region. Preferably the channel potential of the MOS transistor can be controlled via a resistive region, a so-termed well region surrounding the MOS transistor. As the mobility of electrons is much higher than that of holes, the MOS transistor preferably is an NMOS transistor and the bipolar transistor preferably is an NPN transistor.

A method of manufacturing a semiconductor device comprising a substrate and a semiconductor body of silicon which is provided with a semiconductor layer structure comprising, in succession, at least a first and a second semiconductor layer and with a surface region of a first conductivity type which is provided with a field effect transistor with a channel of a second conductivity type, opposite to the first conductivity type, wherein the surface region is provided with source and drain regions of the second conductivity type for the field effect transistor, and with—interposed between said drain regions—a channel region having a low doping concentration which is formed so as to form part of the second semiconductor layer, and with a buried semiconductor region of the first conductivity type which is situated under the channel region and which has a much higher doping concentration than said channel region, and which buried semiconductor region is formed so as to form part of the first semiconductor layer, is characterized in accordance with the invention in that the semiconductor body is provided not only with the field effect transistor but also with a bipolar transistor having an emitter region, a base region and a collector region of, respectively, the second, the first and the second conductivity type, and the emitter region is formed in the second semiconductor layer and the base region is formed in the first semiconductor layer.

Preferably, both the first and the second semiconductor layer are formed by means of epitaxy, the first semiconductor layer being made of a mixed crystal of Si and Ge and the second semiconductor layer being made of Si. Below the SiGe-containing layer, preferably, a graded SiGe-containing buffer layer is formed. The epitaxy process may be advantageously interrupted once or more times to form isolation regions for the electrical isolation of the MOS transistor and the bipolar transistor, or to form the collector region or a so-termed well region.

These and other aspects of the invention are apparent from and will be elucidated with reference to the embodiment(s) described hereinafter.

In the drawings:

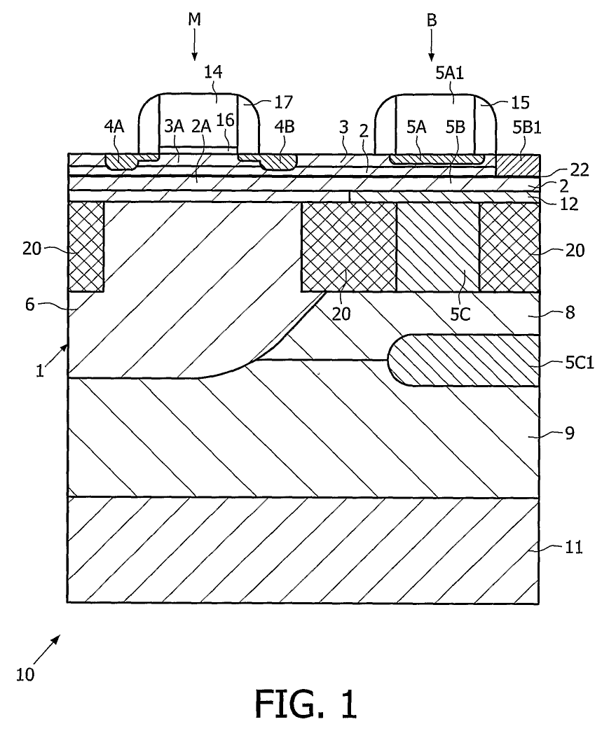

FIG. 1 is a diagrammatic cross-sectional view, at right angles to the thickness direction, of an embodiment of a semiconductor device in accordance with the invention,

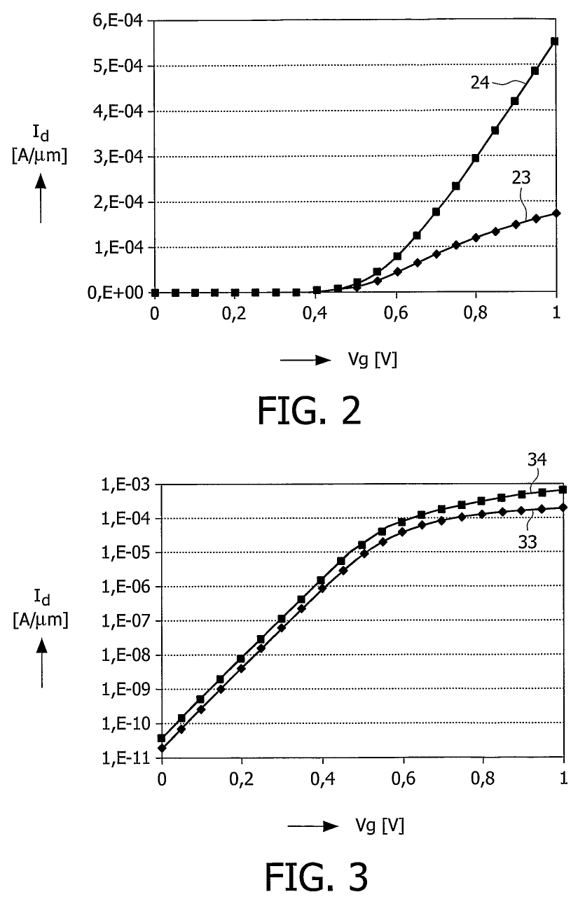

FIG. 2 shows the normalized current (I_{d}) of the MOS transistor of the device of FIG. 1 as a function of the gate voltage (V_{g}) for various drain voltages and on a linear scale,

FIG. 3 shows the results of FIG. 2 on a logarithmic scale,

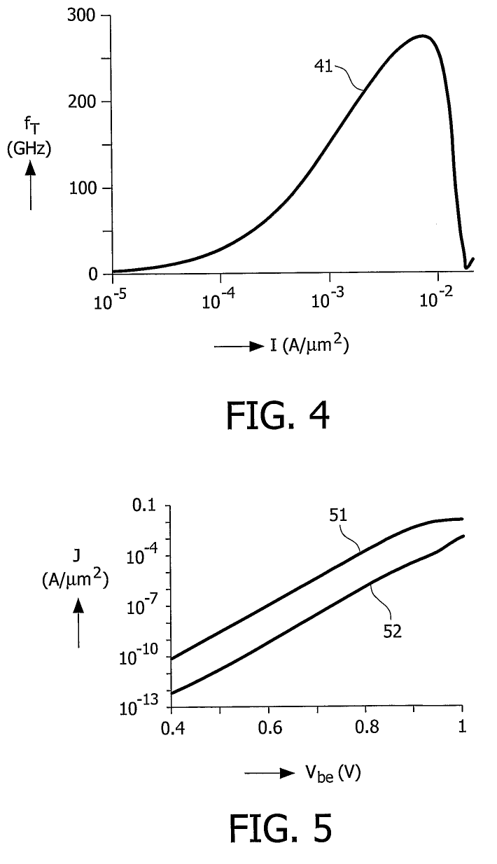

FIG. 4 shows the cut-off frequency (fT) of the bipolar transistor of the device of FIG. 1 as a function of the current density (J),

FIG. 5 shows the current density (J) of the bipolar transistor of the device of FIG. 1 as a function of the base-emitter voltage (Vbe),

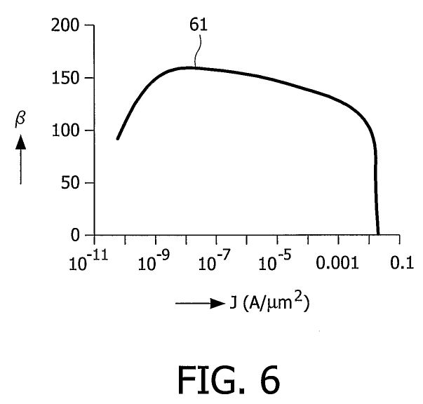

FIG. 6 shows the current gain (β) of the bipolar transistor of the device of FIG. 1 as a function of the current density (J), and

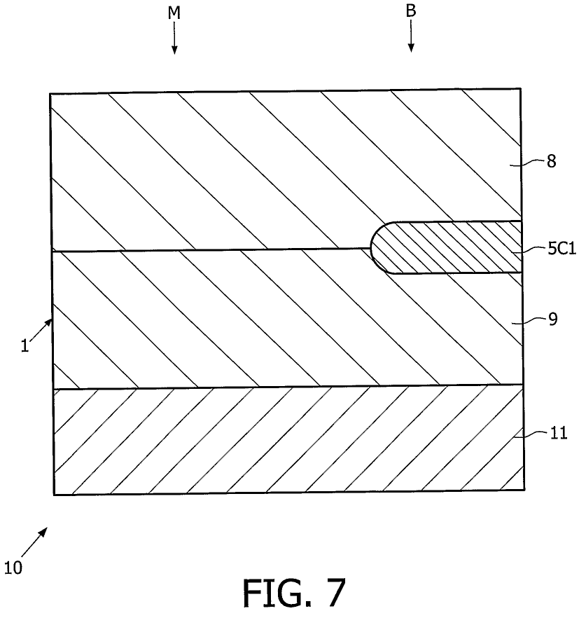

FIGS. 7 through 9 are diagrammatic cross-sectional views, at right angles to the thickness direction, of the device of FIG. 1 in successive stages of the manufacturing process by means of an embodiment of a method in accordance with the invention.

The Figures are not drawn to scale and some dimensions are exaggerated strongly for clarity. Whenever possible, corresponding regions or parts are indicated by means of the same hatching and the same reference numerals.

FIG. 1 is a diagrammatic cross-sectional view, at right angles to the thickness direction, of an embodiment of a semiconductor device in accordance with the invention. The device 10 of this example comprises (see FIG. 1) a substrate 11, in this case a p-type silicon substrate, and a semiconductor layer structure comprising a first semiconductor layer 2, here of SiGe and p-type doped, and a second semiconductor layer 3, here of Si that is lightly doped, in which both a MOS transistor M and a bipolar transistor B are formed. Between the first semiconductor layer 2 and the substrate there is, in this case, a further part of the semiconductor layer structure comprising in succession: another, n-type, semiconductor layer 9 of SiGe whose Ge content increases from approximately zero to approximately the Ge content of the first semiconductor layer 2 and a further n-type semiconductor layer 8 of SiGe whose Ge content is the same as that of the first semiconductor layer 1, i.e. in this case approximately 25 at. %. The semiconductor layer structure is formed by means of epitaxy.

The epitaxial growth process is interrupted a first time between the growth of the further semiconductor layer and the other semiconductor layer 8,9 in order to locally form a buried collector connection region 5C1 by means of a suitable local ion implantation. After the formation of the further semiconductor layer 8, the growth process is interrupted a second time in order to form, at this stage recessed, isolation regions 20, in this case so-termed trench-isolation regions 20, in the surface of the semiconductor body 1. At this stage, also a p-type well region 6 is formed in the semiconductor body 1 at the location of the MOS transistor to be formed, and at the location of the bipolar transistor to be formed a highly doped collector region 5C is formed, both regions being formed by means of suitable local ion implantations. Below the first semiconductor layer 2 there is a thin, lightly doped buffer layer 12 having the same SiGe content as the first semiconductor layer 2.

The first semiconductor layer 2 is provided with a spike or delta-shaped p-type doping profile 22, as a result of which a portion 2A of this layer forms a highly doped p-type ground area 2A at the location of the NMOS transistor M, and another portion 5B forms a highly doped base region 5B at the location of the bipolar transistor B. A portion 3A of the second semiconductor layer 3 containing, in this case, “strained” silicon forms a channel region 3A of the MOST M and, in another portion, an emitter region 5A is formed at the location of the bipolar transistor B by means of outdiffusion of suitable, here n-type, doping atoms from a polycrystalline silicon region 5A1 which serves as emitter connection region 5A1. In said region there is also formed a base connection region 5B1 which is separated from the emitter 5 by means of an isolating spacer 15. The MOS transistor M further comprises a gate electrode 14, here also made of polycrystalline silicon, which is separated from the channel region 3A by a gate dielectric 16, here of silicon dioxide, and which is delimited by isolating spacers 17. The source and drain regions 4A, 4B adjacent thereto are provided with shallow lightly doped extensions which extend as far as the gate dielectric 16.

The device 10 of this example has excellent high-frequency properties and is very suitable for ICs used for applications such as mobile telephony, optical networks and anti-collision robot systems. The bipolar part of the device 10 then serves as a high-frequency transmission/receiving part, while the (C)MOS part is used for high-frequency signal processing. In addition, the device is very suitable for further miniaturization in future sub-micron process technology and, in any case, can be manufactured very easily, as will be explained in greater detail hereinbelow. First, the favorable properties of the device 10 in accordance with the invention will be further illustrated hereinbelow.

FIG. 2 shows the normalized current (I_{d}) of the MOS transistor of the device of FIG. 1 as a function of the gate voltage (V_{g}) for different drain voltages and on a linear scale, while FIG. 3 shows the same results on a logarithmic scale. Curves 23, 33 are obtained for a drain voltage Vd of 50 mV, whereas for curves 24, 34, this voltage V was 1 V. In particular from FIG. 3 it can be derived that the sub-threshold slope is 85 mV/decade and the DIBL (=Drain Induced Barrier Lowering) is 23 mV. These values are indicative of excellent control of the short-channel effects in the device in accordance with the invention. Such values must be considered unattainable for many of the known schemes.

FIG. 4 shows the cut-off frequency (fT) of the bipolar transistor of the device of FIG. 1 as a function of the current density (J). The resultant curve 41 of this Figure shows that the bipolar transistor has a very favorable high-frequency characteristic. The maximum cut-off frequency fr exceeds 250 GHz.

FIG. 5 shows the current density (J) of the bipolar transistor of the device of FIG. 1 as a function of the base-emitter voltage (Vbe) in the forward active mode. Curve 51 corresponds to the collector current Ic and curve 52 corresponds to the base current Ib, while the associated collector-base voltage is zero. This so-termed Gummel plot shows that the bipolar transistor has substantially ideal properties.

FIG. 6 shows the current gain (β) of the bipolar transistor of the device of FIG. 1 as a function of the current density (J). Curve 61 shows that a high gain in excess of 100 is attainable over a wide range of current densities.

The device 10 of this example can be manufactured, inter alia, in the way described hereinbelow.

FIGS. 7 through 9 are diagrammatic cross-sectional views, at right angles to the thickness direction, of the device of FIG. 1 in successive stages of the manufacturing process by means of an embodiment of a method in accordance with the invention. For the starting material use is made (see FIG. 7) of a p-type substrate 11 of silicon. On this substrate there is provided an n-type buffer layer 9 in a thickness of 3500 nm which comprises Si—Ge and whose Ge content increases from approximately 0 at. % to approximately 35 at. %. Next, the growth process is interrupted and an n+ connection region 5C1 is locally formed, by means of a mask, for the bipolar transistor B to be formed. Subsequently, a 500 nm thick Si—Ge layer 8 is provided whose Ge content is approximately 35 at. %.

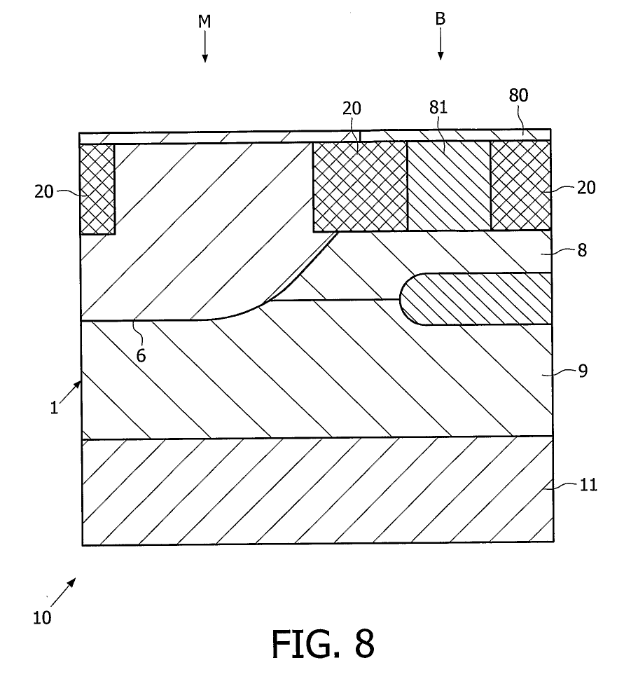

Subsequently (see FIG. 8), isolation regions 20 are formed, here in the form of so-termed trench-isolation regions 20 which are recessed in the semiconductor body and filled with, for example, silicon dioxide. Next, the epitaxy process is continued by applying the buffer layer 80, in this case of n-type Si—Ge. Subsequently, by means of local ion implantations and a suitable mask, a p-type well region 6 is formed at the location of the MOS transistor M to be formed and an n+-type collector region 81 is formed at the location of the bipolar transistor B to be formed.

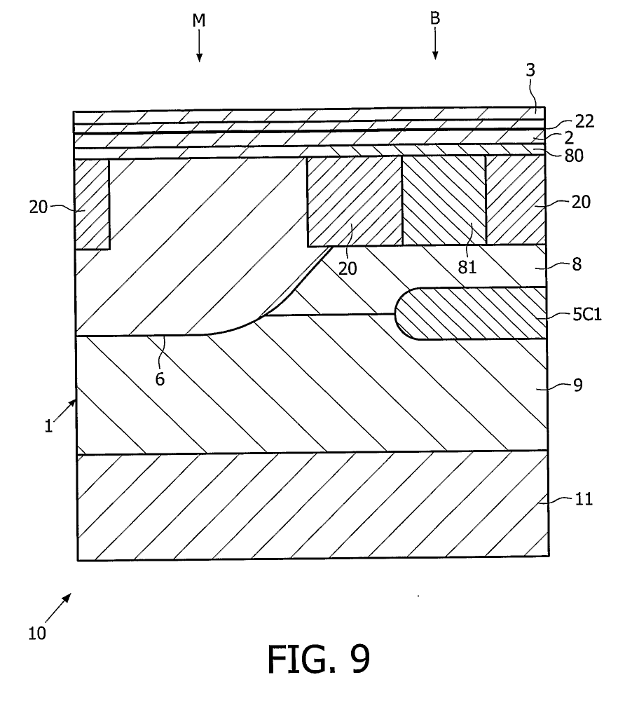

Subsequently (see FIG. 9), the growth process is resumed by providing the first semiconductor layer 2 of Si—Ge in a thickness ranging from 20 to 40 nm, the Ge content being the same as that of the Si—Ge layer 8. During its growth process, the layer 2 is provided with a high doping spike 22 of p-type doping elements, in this case boron atoms. Next, the growth process is completed by growing the second semiconductor layer 3 of strained silicon, which is lightly (p-type) doped and has a thickness in the range of 5 to 10 nm.

Next (see FIG. 1), in a manner known per se, the MOS transistor M and bipolar transistor B to be formed are completed by adding the missing parts, which were mentioned hereinabove during the description of the device 10 of this example. A small number of parts were not mentioned and not shown in the drawing; they include connection conductors, contact metallization, whether or not in the form of so-termed bond pads, and one or more insulating and/or conductive and/or semiconductive layers necessary for said contact metallization, as well as passivation and/or protective layers which may or may not be used. Individual devices 10 ready for final assembly are subsequently obtained after a separation process such as dicing.

The invention is not limited to the exemplary embodiments given hereinabove, and within the scope of the invention many variations and modifications are possible to those skilled in the art. For example, the invention cannot only be used in a BiMOS but also in a BiCMOS (=Bipolar Complementary Metal Oxide Semiconductor) IC (=Integrated Circuit). The invention can also be applied to PMOS transistors in combination with a PNP transistor. It is further noted that instead of STI isolation regions use may alternatively be made of isolation regions obtained by means of the LOCOS (=Local Oxidation Of Silicon) technique. The structure of a device in accordance with the invention may be formed so as to comprise one or more mesa-shaped parts, but also so as to be (substantially) entirely planar. Besides a mixed crystal of Si—Ge use can also advantageously be made of other mixed crystals such as a mixed crystal of Si and C.

As regards a method in accordance with the invention it equally applies that many variations and modifications are possible. For example, the highly doped part of the emitter region may alternatively be formed by means of outdiffusion from in situ-doped polycrystalline silicon or by means of gas-phase doping.

1. A semiconductor device comprising a substrate and a semiconductor body of silicon having a semiconductor layer structure including, in succession, at least a first and a second semiconductor layer and having a surface region of a first conductivity type which is provided with a field effect transistor with a channel of a second conductivity type, opposite to the first conductivity type, wherein the surface region is provided with source and drain regions of the second conductivity type for the field effect transistor and with—interposed between said source and drain regions—a channel region with a low doping concentration which forms part of the second semiconductor layer and with a buried semiconductor region of the first conductivity type which is situated under the channel region and which has a doping concentration that is much higher than that of the channel region and which forms part of the first semiconductor layer characterized in that the semiconductor body is provided not only with said field effect transistor but also with a bipolar transistor having an emitter region, a base region and a collector region of, respectively, the second, the first and the second conductivity type, and the emitter region is formed in the second semiconductor layer and the base region is formed in the first semiconductor layer.

2. A semiconductor device as claimed in claim 1, characterized in that the first and the second semiconductor layer are formed by means of epitaxy.

3. A semiconductor device as claimed in claim 1, characterized in that the first semiconductor layer contains a mixed crystal of silicon and germanium, and the second semiconductor layer contains silicon.

4. A semiconductor device as claimed in claim 3, characterized in that the thickness of the first semiconductor layer or of a further semiconductor layer bordering the first semiconductor layer, preferably, on the lower side thereof and containing a mixed crystal of silicon and germanium is so dimensioned that the second semiconductor layer is mechanically stressed.

5. A semiconductor device as claimed in claim 3, characterized in that below the first semiconductor layer and below a further semiconductor layer adjoining said first semiconductor layer, another semiconductor layer is situated containing a mixed crystal of silicon and germanium, the germanium content gradually increasing, in the direction of the first semiconductor layer from zero to the germanium content of the first semiconductor layer.

6. A semiconductor device as claimed in claim 1, characterized in that the first semiconductor layer is provided with a concentration profile of doping atoms for the first conductivity type having a delta character in the thickness direction.

7. A semiconductor device as claimed in claim 1, characterized in that the emitter region of the bipolar transistor is formed in the second semiconductor layer by locally introducing doping atoms for the second conductivity type into said second semiconductor layer.

8. A semiconductor device as claimed in claim 1, characterized in that the channel potential of the MOS transistor can be controlled via a resistor-forming connection region for a so-termed well region surrounding the MOS transistor.

9. A semiconductor device as claimed in claim 1, characterized in that the first conductivity type is the p-conductivity type, as a result of which the MOS transistor is an NMOS transistor and the bipolar transistor is an NPN transistor.

10. A method of manufacturing a semiconductor device comprising a substrate and a semiconductor body of silicon which is provided with a semiconductor layer structure comprising, in succession, at least a first and a second semiconductor layer and with a surface region of a first conductivity type which is provided with a field effect transistor with a channel of a second conductivity type, opposite to the first conductivity type, wherein the surface region is provided with source and drain regions of the second conductivity type for the field effect transistor, and with—interposed between said source and drain regions—a channel region having a low doping concentration which is formed so as to form part of the second semiconductor layer and with a buried semiconductor region of the first conductivity type which is situated under the channel region and which has a much higher doping concentration than said channel region and which buried semiconductor region is formed so as to form part of the first semiconductor layer characterized in that the semiconductor body is provided not only with the field effect transistor but also with a bipolar transistor having an emitter region, a base region and a collector region of, respectively, the second, the first and the second conductivity type, and the emitter region is formed in the second semiconductor layer and the base region is formed in the first semiconductor layer.

11. A method as claimed in claim 10, characterized in that the first and the second semiconductor layer are formed by means of epitaxy.

12. A method as claimed in claim 11, characterized in that the first semiconductor layer is made of a mixed crystal of silicon and germanium, and the second semiconductor layer is made of silicon.

13. A method as claimed in claim 12, characterized in that below the first semiconductor layer and below an adjoining further semiconductor layer of a mixed crystal of silicon and germanium, a further semiconductor layer is formed of a mixed crystal of silicon and germanium whose germanium content increases in the direction of the first semiconductor layer.

14. A method as claimed in claim 12, characterized in that the epitaxial growth of the semiconductor layer structure is interrupted once or more times for providing isolation regions for the electrical isolation of the MOS transistor and the bipolar transistor or to form parts of the collector region or to form a so-termed well region.
